(19) United States
(12) Patent Application Publication
(10) Pub. No.: US 2026/0123120 A1
(43) Pub. Date: Apr. 30, 2026

(54) MICRO-OPTOELECTRONIC CHIP, FABRICATION METHOD THEREFOR, AND APPLICATION THEREOF

(71) Applicant: SUZHOU INSTITUTE OF NANO-TECH AND NANO-BIONICS (SINANO) , CHINESE ACADEMY OF SCIENCES, Suzhou (CN)

(72) Inventors: Xiaodong ZHANG, Suzhou (CN); Xianhai XIA, Suzhou (CN); Qiang ZHA, Suzhou (CN); Zhongming ZENG, Suzhou (CN); Baoshun ZHANG, Suzhou (CN)

(73) Assignee: SUZHOU INSTITUTE OF NANO-TECH AND NANO-BIONICS (SINANO) , CHINESE ACADEMY OF SCIENCES, Suzhou (CN)

(21) Appl. No.: 19/477,805

(22) PCT Filed: Jun. 19, 2023
(86) PCT No.: PCT/CN2023/101115

§ 371 Date: Oct. 23, 2025

(30) Foreign Application Priority Data
Apr. 26, 2023 (CN) 202310462826.9

(51) Int. Cl. H10H 20/855; H10H 20/01; H10H 20/819; H10H 20/824

(52) U.S. Cl. CPC H10H 20/855; H10H 20/0133; H10H 20/0363; H10H 20/819; H10H 20/824

(57) ABSTRACT

Provided are a micro-optoelectronic chip, a fabrication method therefor, and application thereof. The micro-optoelectronic chip includes a semiconductor structure layer, including a first doped semiconductor layer, an active layer and a second doped semiconductor layer stacked on a substrate in turn; an ion-implanted region distributed in the semiconductor structure layer, where the ion-implanted region is configured to electrically isolate multiple optoelectronic chip structures arranged in an array in the semiconductor structure layer; an isolation trench, formed in the corresponding ion-implanted region and at least configured to isolate second doped semiconductor layers of any two adjacent optoelectronic chip structures from each other; and a light-blocking structure, arranged in the isolation trench and configured to prevent light from transmitting between any two adjacent optoelectronic chip structures through the second doped semiconductor layer. An optical crosstalk problem can be effectively eliminated. The micro-optoelectronic chip has excellent photoelectric conversion efficiency and display effect.

### CROSS-REFERENCE TO THE RELATED APPLICATIONS

This application is the national phase entry of International Application No. PCT/CN2023/101115, filed on Jun. 19, 2023, which is based upon and claims priority to Chinese Patent Application No. 202310462826.9, filed on Apr. 26, 2023, the entire contents of which are incorporated herein by reference.

### TECHNICAL FIELD

The present disclosure relates to a semiconductor optoelectronic device, and in particular to a micro-optoelectronic chip, a fabrication method therefor, and application thereof, belonging to the technical field of fabrication of semiconductor devices.

### BACKGROUND

Micro-LED is an ideal novel micro-display technology. Micro-LED array can be combined with an active silicon-based display driver chip by chip flip or wafer-level bonding technology to form a self-luminous Micro-LED micro-display chip with high luminous efficiency and better color performance. Compared with an LCD (Liquid Crystal Display), the self-luminous Micro-LED micro-display chip does not need backlight, so there is no need to match with various condensing and projecting optical components, and the volume of an optical machine can be greatly reduced. In addition, each Micro-LED pixel can be independently switched on and off, and the light efficiency and dynamic contrast can be significantly improved. Compared with an OLED (Organic Light Emitting diode) made of an organic material, (GaN) Micro-LED, an inorganic material, has a wider operating temperature range and can withstand higher current density. The microchip can achieve a brightness of up to one million nits, which is tens to hundreds of times brighter than the OLED displays. This makes it suitable for specialized application scenarios, including defense and military applications.

At present, the mainstream technical approach for Micro-LEDs involves first processing on the basis of conventional LEDs using semiconductor micro/nano-fabrication techniques like dry etching (such as RIE (Reactive Ion Etching), ECR (Electron Cyclotron Resonance), ICP (Inductively Coupled Plasma)) to obtain Micro-LED chips with dimensions of tens of microns or even smaller. This is followed by employing massively parallel transfer technology or monolithic array integration technology to achieve full-color RGB (Red-Green-Blue) image display. However, the dry etching process leaves a sidewall on an edge of the Micro-LED chip, high-energy etching particles bombard the material lattice to form defective dangling bonds on the surface of the material, and these etching particles can also be implanted into the material, causing sidewall damage that extends several micrometers into the chip interior. The presence of these damages introduces a large number of defect energy levels at an edge region of the Micro-LED. The dangling bonds mean increasing the leakage pathway of carriers, which is unacceptable for the Micro-LED micro-display device with better optical and electrical characteristics. Specifically, these defects and damages greatly reduce quantum efficiency and usable area of the Micro-LED device. For example, the usable area of 5 μm×5 μm Micro-LED chip is only about 4% of its total size due to the sidewall damage effect. In addition, the sidewall damage defect forms a deep energy level as a non-radiative recombination center in the material, which greatly increases a non-radiative recombination rate of the device and makes peak luminous efficiency of the Micro-LED usually lower than 10%. Furthermore, there are serious optical crosstalk between the etched Micro-LED chips, which seriously affects a micro-display effect of the Micro-LED display in use. For example, the light emission from the Micro-LED pixel may cause adjacent Micro-LED pixels to emit light. When it is necessary for the areas surrounding the luminous pixel to be black during display to enhance a contrast ratio, the contrast ratio of the micro-display can be greatly reduced due to the presence of the optical crosstalk. Still further, due to the dispersion of light transmission caused by the optical crosstalk, the brightness of local Micro-LED can also be greatly reduced.

In recent years, the researchers have found that the ion implantation isolation method is expected to effectively avoid the degradation of Micro-LED device array performance due to sidewall damage caused by an etching process and reduce the influence of a groove structure on the preparation process cost and possible yield of a Micro-LED device array while implementing the miniaturization of LED light-emitting area, and the fabricated Micro-LED device array is also expected to have the advantages of planarization. However, the ion implantation isolation method has obvious shortcomings in the preparation process of the Micro-LED device array. For example, the Micro-LED device array prepared by using the ion implantation isolation method cannot achieve real optical isolation, which is not conducive to reducing optical crosstalk between Micro-LED devices and has an impact on the display effect of the final Micro-LED micro-display device. In particular, with the continuous reduction of the size of the Micro-LED chip and the distance between adjacent chips, the size of the ion-implanted region needs to be reduced accordingly. Transverse beam expansion leads to more serious optical crosstalk between adjacent Micro-LED chips, further resulting in the further reduction of color uniformity and resolution of the Micro-LED chips.

### SUMMARY

A main objective of the present disclosure is to provide a micro-optoelectronic chip, a fabrication method therefor, and application thereof, thereby solving disadvantages in the prior art

To implement the foregoing objective, the present disclosure employs the technical solution as follows.

One aspect of the present disclosure provides a micro-optoelectronic chip, including:
a substrate;
a semiconductor structure layer disposed on the substrate, where the semiconductor structure layer includes a first doped semiconductor layer, an active layer and a second doped semiconductor layer which are stacked on the substrate in turn;
an ion-implanted region and an isolation trench distributed in the semiconductor structure layer, where the ion-implanted region is configured to electrically isolate multiple optoelectronic chip structures arranged in an array in the semiconductor structure layer;
an isolation trench formed in the ion-implanted region, where the isolation trench is at least configured to isolate second doped semiconductor layers of any two adjacent optoelectronic chip structures from each other; and
a light-blocking structure arranged in the isolation trench, where the light-blocking structure is at least configured to prevent light from transmitting between any two adjacent optoelectronic chip structures through the second doped semiconductor layer.

Another aspect of the present disclosure provides a fabrication method for a micro-optoelectronic chip, including the following steps:
forming a semiconductor structure layer on a substrate, where the semiconductor structure layer includes a first doped semiconductor layer, an active layer and a second doped semiconductor layer which are stacked on the substrate in turn;
carrying out ion implantation processing on the semiconductor structure layer to form an ion-implanted region in the semiconductor structure layer, thereby electrically isolating multiple optoelectronic chip structures arranged in an array in the semiconductor structure layer;
etching the ion-implanted region to form an isolation trench in the ion-implanted region, thereby at least isolating second doped semiconductor layers of any two adjacent optoelectronic chip structures from each other; and
arranging a light-blocking structure in the isolation trench to at least prevent light from transmitting between any two adjacent optoelectronic chip structures through the second doped semiconductor layer.

A still another aspect of the present disclosure provides application of the micro-optoelectronic chip in preparation of am optoelectronic device, where the optoelectronic device includes, but is not limited to, a display device, a micro-display device, and the like.

Compared with the prior art, the technical solution of the present disclosure eliminates an optical crosstalk problem between chips in the array while implementing the preparation of a micro-optoelectronic chip array in an ion implantation manner, so that the micro-optoelectronic chip array has excellent photoelectric conversion efficiency and display effect.

### BRIEF DESCRIPTION OF THE DRAWINGS

The accompanying drawings, which constitute a part of the present disclosure, serve to provide a further understanding of the present disclosure. Illustrative embodiments of the present disclosure and descriptions thereof are used to explain the present disclosure and do not constitute undue limitations on the present disclosure.

FIG. 1 is a diagram of a Micro-LED chip according to Embodiment 1;

FIG. 2 is a diagram of a structure of an epitaxial wafer of a Micro-LED chip according to Embodiment 1;

FIG. 3 is a diagram of a structure of a device formed after carrying out ion implantation on an epitaxial wafer shown in FIG. 2;

FIG. 4 is a diagram of a structure of a device formed by etching and slotting an ion-implanted region of a device shown in FIG. 3;

FIG. 5 is a diagram of a structure of a device formed by filling an isolation trench of a device shown in FIG. 4 with a light-blocking structure;

FIG. 6 is a diagram of a Micro-LED chip according to Embodiment 3;

FIG. 7 is a partial enlarged view of region A in FIG. 6;

FIG. 8 is a test chart of reflectivity of a dielectric layer for light with different wavelengths according to Embodiment 3;

FIG. 9 is a test chart of reflectivity of a dielectric layer for light with different wavelengths according to Embodiment 4;

FIG. 10 is a test chart of reflectivity of a dielectric layer for light with different wavelengths according to Embodiment 5.

### DETAILED DESCRIPTION OF THE EMBODIMENTS

In view of the problem of sidewall damage in a micro-optoelectronic chip array formed by using a conventional etching process and the defect of optical crosstalk existing in micro-optoelectronic chip array formed by using an ion implantation isolation way, the applicant has been able to put forward the technical solution of the present disclosure after long-term research and practice, so that the influence of the optical crosstalk that may affect the final display effect can be reduced, and the advantage that ion implantation isolation means is conducive to improving the photoelectric conversion efficiency is maintained, thereby improving the photoelectric performance of the micro-optoelectronic chip array and optimizing display effect thereof. The technical solution of the present disclosure is further described in detail below.

A micro-optoelectronic chip provided by some embodiments of the present disclosure includes:
a substrate;
a semiconductor structure layer disposed on the substrate, where the semiconductor structure layer includes a first doped semiconductor layer, an active layer and a second doped semiconductor layer which are stacked on the substrate in turn;
an ion-implanted region and an isolation trench distributed in the semiconductor structure layer, where the ion-implanted region is configured to electrically isolate multiple optoelectronic chip structures arranged in an array in the semiconductor structure layer;
an isolation trench formed in the ion-implanted region, where the isolation trench is at least configured to isolate second doped semiconductor layers of any two adjacent optoelectronic chip structures from each other; and
a light-blocking structure arranged in the isolation trench, where the light-blocking structure is at least configured to prevent light from transmitting between any two adjacent optoelectronic chip structures through the second doped semiconductor layer.

In the present disclosure, the micro-optoelectronic chip array is implemented by using an ion implantation isolation way. By forming an isolation trench in the ion-implanted region and disposing a light-blocking structure in the isolation trench, the miniaturization of the chip can be achieved better, the damage to a sidewall of the chip and a dangling bond caused by the etching process can be avoided, the quantum efficiency and effective use area of the chip are ensured and increased, so that the micro-optoelectronic chip array has better optical and electrical characteristics. In addition, the light can be prevented from transmitting between adjacent chips in the micro-optoelectronic chip array, the optical crosstalk is eliminated, and the display effects such as contrast ratio and brightness of the micro-optoelectronic chip array are improved.

In one embodiment, the ion-implanted region extends continuously at least from a top end surface of the second doped semiconductor layer to a top end surface of the active layer, the whole isolation trench is located in the ion-implanted region, a bottom surface of the isolation trench is higher than a bottom end surface of the ion-implanted region and is flush with a bottom end surface of the second doped semiconductor layer or lower than the bottom end surface of the second doped semiconductor layer, and the top end surface of the second doped semiconductor layer is one side surface, away from the substrate, of the second doped semiconductor layer. In a way of placing the whole isolation trench in the ion-implanted region, a risk of damaging a semiconductor material caused by etching in the process of fabricating the isolation trench can be further reduced, and a heat-conduction filling material in the isolation trench can be electrically isolated from a semiconductor material in the structure layer such as the second doped semiconductor layer and the active layer through the ion-implanted region, thereby ensuring normal operating performance of the device.

Implanted ions for forming the ion-implanted region include, but are not limited to, H ions, F ions, N ions, or O ion.

There may be one or more ion-implanted region. As an example, on a surface of the semiconductor structure layer, the ion-implanted region may be grid-shaped, and a region surrounded by various grids is a non-ion-implanted region, which is used for the fabrication of the optoelectronic chip structure. Correspondingly, there may be one or more isolation trenches. As an example, the isolation trench may also be grid-shaped on the surface of the semiconductor structure layer.

In the present disclosure, the ion-implanted region is arranged around a corresponding non-ion-implanted region, and an optoelectronic chip structure is formed in the corresponding non-ion-implanted region. The size of each of the ion-implanted region and the optoelectronic chip structure may be determined according to actual needs. As an example, the size of each of the ion-implanted region and the optoelectronic chip structure ranges from 1 um to 50 um. The size of each of the ion-implanted region and the optoelectronic chip structure mainly means its size in a direction parallel to a layer plane of the semiconductor structure layer, or may be considered as its length and width or its diameter.

Further, the bottom end surface of the ion-implanted region may be located in the first doped semiconductor layer, a notch of the isolation trench may be arranged on the top end surface of the second doped semiconductor layer, while the bottom of the isolation trench is located in the first doped semiconductor layer. The light-blocking structure is at least configured to prevent light from transmitting between any two adjacent optoelectronic chip structures through the second doped semiconductor layer and the active layer. Such a design can block the transmission of the light in the micro-optoelectronic chip array better and overcome the problem of optical crosstalk more thoroughly.

In the present disclosure, there is a certain distance from an inner wall of the isolation trench to an outer wall of the corresponding ion-implanted region, that is, the ion-implanted region has a certain wall thickness, which, for example, may be 100 nm to 20 μm.

In an embodiment, the micro-optoelectronic chip further includes at least one dielectric layer, and the dielectric layer continuously covers at least a sidewall of the isolation trench and is located between the sidewall of the isolation trench and the light-blocking structure. In addition, the light-blocking structure includes a metal optical isolation layer that continuously covers at least the dielectric layer. By arranging the dielectric layer, the sidewall of the isolation trench can be protected, and a heat-conduction filling material in the isolation trench can be further electrically isolated from a semiconductor material in the structure layer such as the second doped semiconductor layer, the active layer, and the like. The dielectric layer may also prevent ions in the ion-implanted region from escaping when the metal optical isolation layer is fabricated by using evaporation and other processes, thereby ensuring the operation performance of the device better.

A material of the dielectric layer comprises silicon oxide, silicon nitride, aluminum nitride, aluminum oxide, gallium oxide, titanium oxide, or hafnium oxide, but is not limited thereto.

A material of the metal optical isolation layer comprises gold, titanium, aluminum, nickel, chromium, molybdenum, or copper, but is not limited thereto. Preferably, the material of the metal optical isolation layer comprises Al and other metals or alloys with excellent reflective and conductive properties. The metal optical isolation layer may be of a single-layer or multi-layer structure.

More preferably, the micro-optoelectronic chip includes multiple dielectric layers with different refractive indexes, and the multiple dielectric layers are stacked on at least the sidewall of the isolation trench in turn and combined with the ion-implanted region to form a distributed Bragg reflector structure (DBR). The definition of the distributed Bragg reflector structure is known in the art, which is an optical film mainly composed of a low-refractive-index material and a high-refractive-index material through different stacking combinations. For example, the low-refractive-index material may employ, but is not limited to, SiO₂ and the like, and the high-refractive-index material may be selected from, but not limited to, TiO₂, Ta₂O₅, ZrO₂, and the like. The greater a refractive index difference between the materials, the smaller a thickness to achieve the required reflectivity.

Specifically, after the ion-implanted region is formed by ion implantation in a selected region of the semiconductor structure layer, the refractive index of the semiconductor material may also change accordingly, so that the semiconductor material can form a photorefractive interface with the semiconductor material in the chip, and then a DBR structure can be formed by alternately stacking multiple dielectric layers with different refractive indexes on the sidewall of the isolation trench, which not only can achieve sidewall passivation to ensure electrical performance stability and long-term reliability of the optoelectronic chip better, but also can cooperate with the light-blocking structure to optically isolate and totally reflect the light emitted from a sidewall of the optoelectronic chip. Therefore, more light energy can be emitted from the front inside the optoelectronic chip, which can eliminate the problem of optical crosstalk better and further improve the photoelectric conversion efficiency of the chip.

Preferably, the dielectric layer is made of a heat-conduction dielectric material, for example, a thermal expansion coefficient of the heat-conduction dielectric material is between that of a material for the metal optical isolation layer and that of a material for an ion isolation region; and/or the heat-conduction dielectric has good binding performance with the material for the metal optical isolation layer and the material for the ion isolation region. Therefore, it is not only beneficial to transfer the heat generated by the chip operation more quickly, but also can make the metal optical isolation layer more firmly bound with the chip, thereby preventing the metal optical isolation layer from being separated from the chip structure under the influence of the heat generated by the chip after long-term operation. The heat-conduction dielectric material may be selected from, but is not limited to, silicon nitride, aluminum nitride, and the like.

More preferably, the dielectric layer for forming the distributed Bragg reflector structure is made of the heat-conduction dielectric material, thereby giving consideration to both light reflection and heat conduction.

In the present disclosure, the dielectric layer has a thickness from 5 nm to 500 nm.

In one embodiment, the micro-optoelectronic chip further includes a heat-conduction passivation layer, the heat-conduction passivation layer covers the surface of the semiconductor structure layer and is in heat-conduction connection with the metal optical isolation layer. The heat-conduction passivation layer not only can protect the surface of the micro-optoelectronic chip array, but also can form a heat-conduction path with the metal optical isolation layer, which is more conducive to reducing the temperature of the micro-optoelectronic chip array to ensure the operation performance and stability of the micro-optoelectronic chip array.

A material of the heat-conduction passivation layer comprises aluminum nitride, boron nitride, or diamond, but is not limited thereto.

In some cases, a local region of the heat-conduction passivation layer is filled in the isolation trench and is in direct contact with the metal optical isolation layer. Moreover, in some cases, the heat-conduction passivation layer may also be provided with some windows for fabricating electrodes in cooperation with various optoelectronic chip structures.

In one embodiment, the metal optical isolation layer also extends to cover the surface of the semiconductor structure layer to form a current spreading layer.

In the present disclosure, the semiconductor structure layer includes a III-V compound, preferably a III nitride, such as AlₓIn_{y}Ga_{1-x-y}N, 1≥x≥2, 1≥y≥0, and 1≥(1−x−y)≥0. The first doped semiconductor layer and the second doped semiconductor layer have different heat conduction types, for example, the first doped semiconductor layer and the second doped semiconductor layer may be an N-type semiconductor layer and a P-type semiconductor layer, respectively, and vice versa. The active layer may be a multi-quantum well layer. In addition, the semiconductor structure layer may also include other structure layers known in the art, such as a buffer layer. The materials and thicknesses of these structure layers can be selected or set according to the methods known in the art, and thus will not be described in detail here.

In the present disclosure, the substrate may include, but is not limited to, Sapphire, Si, SiC and GaN substrates.

In the present disclosure, the optoelectronic chip structure may include, but is not limited to, a Micro-LED chip structure, or may be an LD (laser device), a Mini-LED chip structure, or other light-emitting semiconductor structures.

A method for fabricating the micro-optoelectronic chip provided by some embodiments of the present disclosure includes the following steps.

A semiconductor structure layer is formed on a substrate, where the semiconductor structure layer includes a first doped semiconductor layer, an active layer and a second doped semiconductor layer which are stacked on the substrate in turn. For example, the first doped semiconductor layer, the active layer and the second doped semiconductor layer can be grown on the substrate in turn by the processes such as metal organic chemical vapor phase epitaxy (MOCVD) or molecular beam epitaxy (MBE).

The semiconductor structure layer is subjected to ion implantation processing to form an ion-implanted region in the semiconductor structure layer, thereby electrically isolating multiple optoelectronic chip structures arranged in an array in the semiconductor structure layer, where the implanted ions include, but are not limited to, H ions, F ion, N ions, or O ions. Generally speaking, the ion-implanted region is arranged around a non-ion-implanted region, and an optoelectronic chip structure is fabricated in the non-ion-implanted region. The size of each of the ion-implanted region and the non-ion-implanted region may be set to 1 μm to 50 μm. To improve effective utilization area of the semiconductor structure layer, the size of the non-ion-implanted region should be as large as possible, while the size of the ion-implanted region should be as small as possible in a reasonable range. The reasonable range should meet the condition that electrical isolation between adjacent chip structures can be achieved, and the forming of the isolation trench is convenient.

The ion-implanted region is etched to form an isolation trench in the ion-implanted region, thereby at least isolating second doped semiconductor layers of any two adjacent optoelectronic chip structures from each other.

A light-blocking structure is disposed in the isolation trench, thereby at least preventing light from transmitting between any two adjacent optoelectronic chip structures through the second doped semiconductor layer.

In one embodiment, the fabrication method specifically includes the following steps.

The ion implantation processing is carried out on the semiconductor structure layer at least from a top end surface of the second doped semiconductor layer, where an ion implantation depth at least reaches a top end surface of the active layer, thereby forming the ion-implanted region.

The ion-implanted region is etched with an etching depth that is less than the ion implantation depth but at least reaches a bottom end surface of the second doped semiconductor layer, thereby forming the isolation trench.

The top end surface of the second doped semiconductor layer is one side surface, away from the substrate, of the second doped semiconductor layer.

In one embodiment, the fabrication method more specifically includes the following steps. The ion implantation processing is carried out on the semiconductor structure layer at least from a top end surface of the second doped semiconductor layer, where an ion implantation depth at least reaches an interior of the first doped semiconductor layer to form the ion-implanted region.

The ion-implanted region is etched with an etching depth that is less than the ion implantation depth but at least reaches the interior of the first doped semiconductor layer to form the isolation trench.

A light-blocking structure is disposed in the isolation trench to prevent light from transmitting between any two adjacent optoelectronic chip structures through the second doped semiconductor layer and the active layer.

In the foregoing embodiments of the present disclosure, a patterned ion implantation mask can be disposed on the surface of the semiconductor structure layer in advance, and the mask is used for the execution of ion implantation. The ion implantation mask can be fabricated in advance and then transferred to the surface of the semiconductor structure layer, or can be fabricated and formed on the surface of the semiconductor structure layer by a lithography process after coating a photoresist layer on the surface of the semiconductor structure layer. A pattern and size of the ion implantation mask correspond to the shape and size of the ion-implanted region, which can be determined based on actual needs. For example, the ion-implanted region may be an annular shape, a square-ring shape, or other regular or irregular shapes.

In the foregoing embodiments of the present disclosure, the ion-implanted region can be etched by using RIE, ECR, ICP and other etching operations, thereby forming the isolation trench. Further, the position, size and shape of the isolation trench can be controlled more accurately by disposing an etching mask on the ion-implanted region and executing an etching operation by using the etching mask, thereby avoiding damage to the sidewall of the chip structure. More preferably, a distance from an edge of an opening of the etching mask to an edge of the ion-implanted region can be controlled at 100 nm to 20 μm, so that a distance from an inner wall of the etched isolation trench to an outer wall of the corresponding ion-implanted region ranges from 100 nm to 20 μm. In practical production, a spacing between high-resistive-state ion-implanted regions can be accurately adjusted by changing the sizes of the foregoing ion implantation mask and the etching mask, thereby flexibly defining the feature size of the chip and achieving preparation of devices with sizes from several microns to hundreds of microns.

In one embodiment, the fabrication method specifically includes the following steps.

At least one dielectric layer is fabricated, so that the dielectric layer can continuously cover at least a sidewall of the isolation trench.

A metal optical isolation layer is fabricated, so that the metal optical isolation layer can continuously cover at least the dielectric layer to form the light-blocking structure.

In the foregoing embodiments of the present disclosure, the dielectric layer can be grown by atomic layer deposition (ALD) and other processes, and its thickness can be set to 5 nm to 500 nm.

More preferably, the fabrication method specifically includes the following steps. Multiple dielectric layers with different refractive indexes are alternately stacked on at least the sidewall of the isolation trench, and the multiple dielectric layers are combined with the ion-implanted region to form a distributed Bragg reflector structure (DBR).

More preferably, the dielectric layer can be formed on at least the sidewall of the isolation trench with a heat-conduction dielectric material, and a thermal expansion coefficient of the heat-conduction dielectric material is between that of a material for the metal optical isolation layer and that of a material for the ion isolation region.

In one embodiment, a heat-conduction passivation layer is formed on the surface of the semiconductor structure layer and is in heat-conduction connection with the metal optical isolation layer. The heat-conduction passivation layer may also be grown and formed by the atomic layer deposition (ALD) and other processes. Preferably, the heat-conduction passivation layer can fully cover the surface of the semiconductor structure layer. Certainly, if an electrode needs to be fabricated, it is also possible to form a corresponding window in the heat-conduction passivation layer.

In one embodiment, the metal optical isolation layer also extends to cover the surface of the semiconductor structure layer to form a current spreading layer. This is conducive to improving luminous uniformity of the micro-optoelectronic chip array.

The materials of the semiconductor structure layer, the dielectric layer, the metal optical isolation layer, the heat-conduction dielectric material and the heat-conduction passivation layer are as described above, and thus will not be described in detail here.

The fabrication method provided by the present disclosure is simple and reliable in process, compatible with the existing process, and capable of improving the effective use area of the chip, reducing damage effect of the sidewall of the material, eliminating the problem of optical crosstalk of the device, and improving luminous efficiency of the device.

In some embodiments of the present disclosure, an optoelectronic device is further provided, including the micro-optoelectronic chip.

In some embodiments of the present disclosure, a fabrication method for an optoelectronic device is further provided, including the following steps.

The micro-optoelectronic chip is fabricated.

An electrode is fabricated, and the electrode is in electrical contact with a first doped semiconductor layer and a second doped semiconductor layer in the optoelectronic chip structure, for example, to form ohmic contact. The electrode includes a P-type electrode and an N-type electrode.

For example, the optoelectronic device may be a Micro-LED device. By using the fabrication method, the Micro-LED chip with smaller size and better optical and electrical characteristics can be fabricated more conveniently, quickly and at low cost, and the resolution and brightness of the chip can be effectively improved to obtain better display effect.

Further, some embodiments of the present disclosure further provides a Micro-LED apparatus, for example, a Micro-LED display device, including the micro-optoelectronic chip.

The implementations of the present disclosure are described below with specific examples, and those skilled in the art can easily understand other advantages and effects of the present disclosure from the contents disclosed in the present disclosure. The present disclosure can also be implemented or applied through other different specific implementations, and various details in this specification can be modified or changed based on different viewpoints and applications without departing from the spirit of the present disclosure.

For example, when the embodiments of the present disclosure are described in detail, for the convenience of explanation, the sectional view showing the device structure will not be partially enlarged in a general proportion, and the schematic diagram is only an example, which should not limit the scope of protection of the present disclosure here. In addition, the three-dimensional dimensions of length, width and depth should be included in the actual fabrication.

For the ease of description, spatial relational words such as “below”, “beneath”, “under”, “lower than”, “above”, or “over” may be used here to describe the relationship between one element or feature shown in the drawings and other elements or features. It should be understood that these spatial relational words are intended to include directions of devices in use or operation other than those depicted in the drawings. In addition, when one layer is called “between” two layers, it may be only layer between the two layers, or there may be one or more intervening layers.

In the context of the present disclosure, the described structure in which a first feature is “above” a second feature may include an embodiment in which the first and second features are in direct contact, or an embodiment in which another feature is formed between the first and second features, in this case, the first and second features may not be in direct contact.

It should be noted that the diagram provided in this embodiment only illustrates the basic idea of the present disclosure in a schematic way, so only the components related to the present disclosure are shown in the diagram instead of being drawn according to the number, shape and size of the components in actual implementation. In actual implementation, the form, quantity and proportion of each component can be changed at will, and their layout may be more complicated.

### Embodiment 1

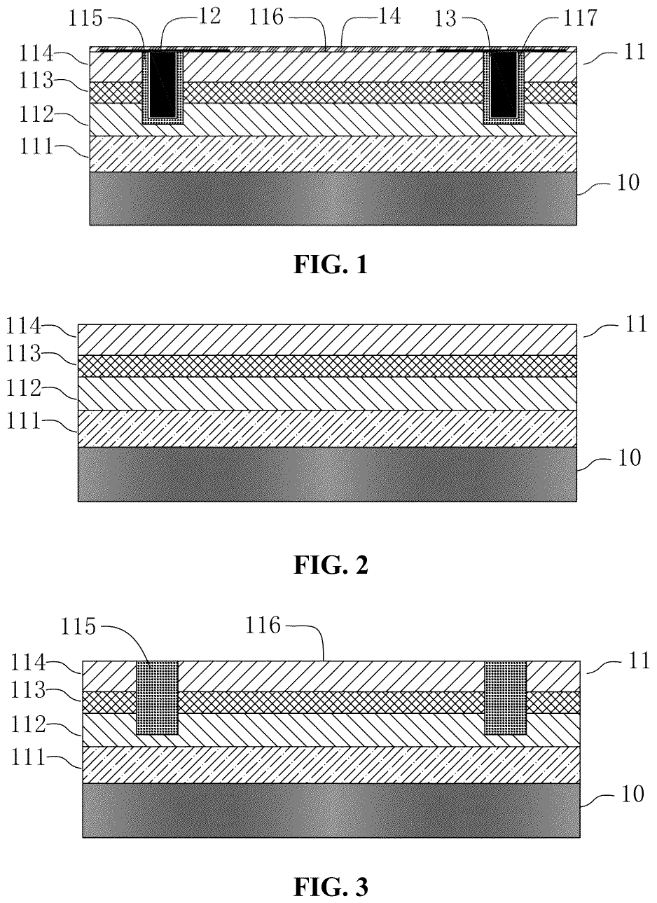

With reference to FIG. 1, this embodiment provides a Micro-LED chip, including a sapphire substrate 10 and a semiconductor structure layer 11. The semiconductor structure layer includes an AIN buffer layer 11, an N-type GaN layer 112, a multi-quantum well active layer 113, and a P-type GaN layer 114 grown on the substrate in turn. The semiconductor structure layer includes an ion-implanted region 115 and multiple non-ion-implanted regions which are distributed along a plane direction of the layer, any two adjacent non-ion-implanted regions are electrically isolated by the ion-implanted region, a Micro-LED chip structure 116 is fabricated in each non-ion-implanted region, and each Micro-LED chip structure 116 may serve as a pixel point, thereby forming the Micro-LED chip structure in the semiconductor structure layer. In addition, an isolation trench 117 is formed in the ion-implanted region to isolate the P-type GaN layer and the multi-quantum well active layer of two adjacent Micro-LED chip structures from each other. A light-blocking structure is further arranged in the isolation trench, which is configured to prevent light from transmitting between two adjacent Micro-LED chip structures through the P-type GaN layer 114 and the multi-quantum well active layer 113. The light-blocking structure includes one or more opaque metal optical isolation layers 12, which mainly includes gold (Au), titanium (Ti), aluminum (Al), nickel (Ni), chromium (Cr), molybdenum (Mo), copper (Cu) or other alloys. The metal optical isolation layer covers an inner wall of the isolation trench, and is mainly used for blocking and reflecting light reflected by the multi-quantum well active layer, thereby blocking a transmission path of the light between adjacent Micro-LED chip structures. One or more dielectric layers 13 are disposed between the metal optical isolation layer and the inner wall of the isolation trench, where the material of the dielectric layer includes silicon oxide (SiO₂), silicon nitride (SiN), aluminum nitride (AlN), aluminum oxide (Al₂O₃), gallium oxide (Ga₂O₃), titanium oxide (TiO₂), or hafnium oxide (HfO₂), but is not limited thereto, and the dielectric layer has a thickness of 5 nm to 500 nm. The dielectric layer is mainly used for passivating the inner wall of the isolation trench and electrically isolating the metal optical isolation layer from the inner wall of the isolation trench. More preferably, the dielectric layer may employ aluminum nitride, silicon nitride, and other materials with high thermal conductivity. In some cases, the isolation trench can be completely filled with the metal optical isolation layer and the dielectric layer. More preferably, the metal optical isolation layer may also continuously extend to cover the surface of the semiconductor structure layer to form a current spreading layer, thereby improving current injection efficiency and uniformity. Further, the surface of the semiconductor structure layer is further covered with a continuous heat-conduction passivation layer 14, which is in direct contact with the metal optical isolation layer, and may include aluminum nitride (AlN), boron nitride (BN), diamond element, and other mixture materials, but is not limited thereto. The heat-conduction passivation layer not only can passivate the surface of the metal optical isolation layer, but also has a function of a Micro-LED heat-conduction layer.

With reference to FIG. 2 to FIG. 5, a fabrication method for the Micro-LED chip includes the following steps.

S1. An AlN buffer layer 111, an N-type GaN layer 112, a multi-quantum well active layer 113 and a P-type GaN layer 114 are grown on a sapphire substrate by MOCVD (Metal Organic Chemical Vapor Deposition), MBE (Molecular Beam Epitaxy), PECVD (Plasma Enhanced Chemical Vapor Deposition) and other ways, thereby obtaining an epitaxial wafer shown in FIG. 2.

S2. A patterned ion implantation mask is formed by lithography and other processes, where a material of the ion implantation mask includes photoresist, silicon oxide, silicon nitride, metal, and the like, but is not limited thereto. The ion implantation mask is used as a blocking layer, a semiconductor structure layer of the epitaxial wafer is subjected to ion implantation, thereby regulating the area and/or shape of a light-emitting region of the Micro-LED chip structure. The ion implantation depth shall at least penetrate the P-type GaN layer, preferably extending into the interior of the N-type GaN layer 112. The implanted ions include, but are not limited to, H ions, F ions, N ions, O ions, and the like. The size of the finally formed ion-implanted region 115 ranges from 1 μm to 50 μm, and the size of the non-ion-implanted region 118 ranges from 1 μm to 50 μm. From the perspective of overlooking, the ion-implanted region 115 is preferably arranged around the non-ion-implanted region 118, and each non-ion-implanted region 118 is configured to form a Micro-LED chip structure. A device structure finally obtained in this step is shown in FIG. 3. In this step, ion implantation is used for electrical isolation. Compared with the way of electrical isolation by etching process, it has the advantages of less damage and high control accuracy.

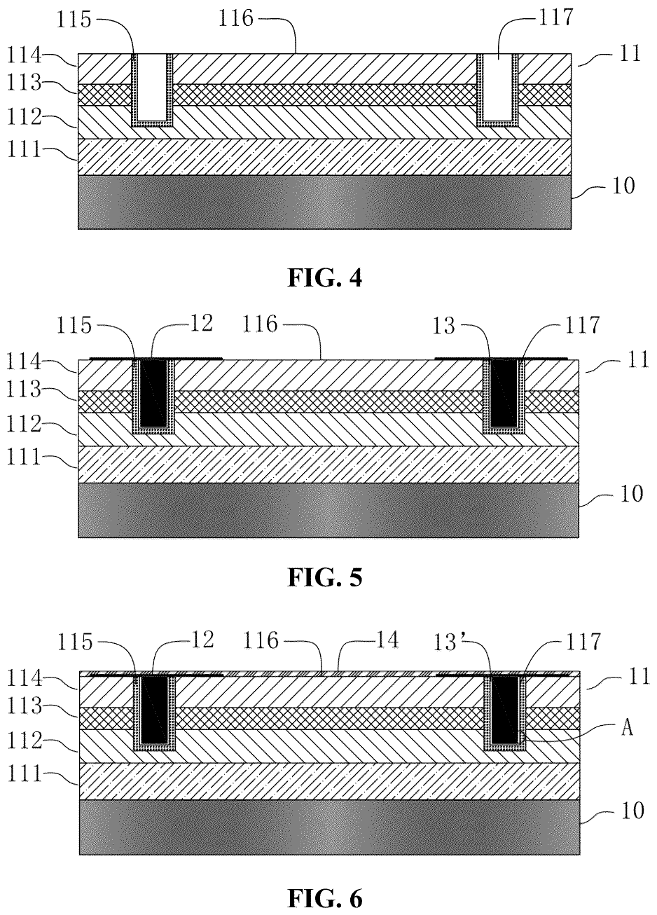

S3. An etching mask is disposed on the ion-implanted region 115, a through hole is formed in the etching mask, and a size of the through hole is smaller than that of the ion-implanted region. More preferably, a distance from an edge of the through hole to an edge of the ion-implanted region ranges from 100 nm to 20 μm, thereby reducing sidewall damage of the chip as much as possible. Furthermore, by using dry etching processes such as atomic layer etching (ALE), ion beam etching (IBE) and inductively coupled plasma etching (ICP), the ion-implanted region is etched through the through hole of the etching mask, and an etching depth is less than or equivalent to the ion implantation depth, but is preferably less than the ion implantation depth, and particularly preferably enters the N-type GaN layer 112 to form the isolation trench 117. The device structure finally obtained in this step is shown in FIG. 4. In this step, dry etching is carried out in the ion-implanted region, which not only can effectively avoid the damage to the sidewall caused by the etching process and improve the photoelectric conversion efficiency, but also can form a narrow etching isolation region, which especially can effectively isolate the light between Micro-LED pixels and eliminate the optical crosstalk effect.

S4. One or more dielectric layers 14 are formed on at least the sidewall of the isolation trench 117 by atomic layer deposition (ALD) and other processes, which has a thickness of 5 nm to 500 nm. In some cases, an inner wall of the isolation trench 117 may be fully covered with a dielectric layer. Further, one or more opaque metal materials are also deposited on the dielectric layer to form the metal optical isolation layer 12, and the light-blocking structure mainly formed by the metal optical isolation layer 12 can effectively reduce the optical crosstalk between pixels. In some cases, the isolation trench 117 can be filled with the metal optical isolation layer 12. A device structure finally obtained in this step is shown in FIG. 5.

S5. A non-metallic heat-conduction material is deposited on the metal optical isolation layer 12 to form a heat-conduction passivation layer 14, and the heat-conduction passivation layer 14 is used for passivating the surface of the metal optical isolation layer 12 and can serve as a heat-conduction layer of the Micro-LED chip structure. More preferably, the heat-conduction passivation layer 14 continuously extends to cover the surface of the device to finally obtain the Micro-LED chip shown in FIG. 1.

### Embodiment 2

A Micro-LED chip provided by this embodiment is basically the same as that of Embodiment 1, the difference is that the dielectric layer is made of aluminum nitride with high thermal conductivity, while the metal optical isolation layer is made of metallic aluminum. On the one hand, the dielectric layer can play a role of passivating the sidewall of the isolation groove and electrically isolating the metal optical isolation layer from the inner wall of the isolation groove; on the other hand, the dielectric layer can serve as a transition layer between the ion-implanted region doped with a GaN material and the metal optical isolation layer, so that the metal optical isolation layer can be firmly bound in the isolation trench, and can form a heat-conduction channel together with the dielectric layer, which is beneficial to quickly transfer the heat generated by the Micro-LED chip during operation to ensure operating stability and improve operating performance.

### Embodiment 3

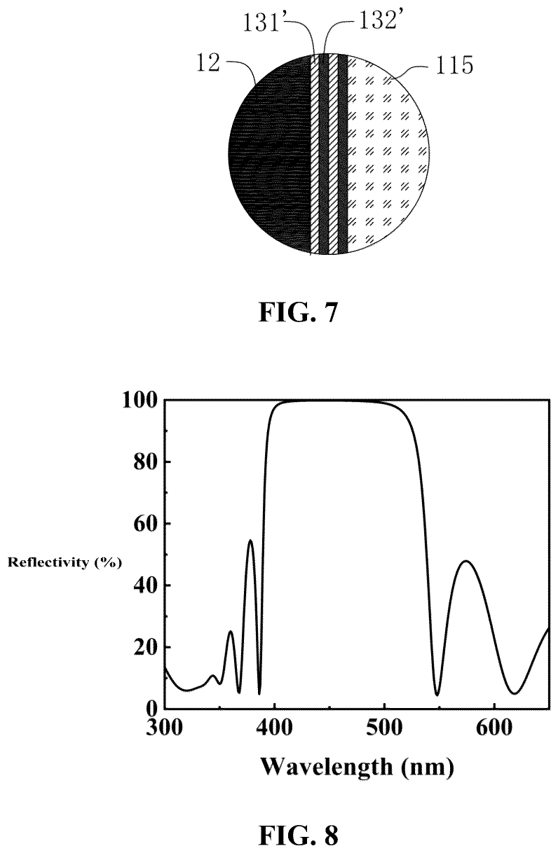

A Micro-LED chip provided by this embodiment is basically the same as that of Embodiment 1, the difference is that the Micro-LED chip structure is a blue-light LED chip structure, which has a central wavelength of about 450 nm. In addition, with reference to FIG. 6 to FIG. 7, the dielectric layer 13′is a structure of eight pairs of TiO₂/SiO₂ composite layers, a total thickness of the dielectric layer 13′is 895.2 nm, where the TiO₂ layer and the SiO₂ layer are alternately stacked to form a distributed Bragg reflector structure, each TiO₂ layer has a thickness of about 41.1 nm, and each SiO₂ layer has a thickness of about 70.8 nm. The reflectivity of the dielectric layer 13′for light with different wavelengths is shown in FIG. 8, which can cooperate with the metal optical isolation layer (for example, a metal aluminum layer) to thoroughly eliminate the problem of optical crosstalk. In addition, the dielectric layer can also be used as a transition layer between the ion-implanted region doped with a GaN material and the metal optical isolation layer to strengthen a bonding force between the metal optical isolation layer and a trench wall of the isolation trench and construct a new heat-conduction channel of the Micro-LED chip with the metal optical isolation layer.

### Embodiment 4

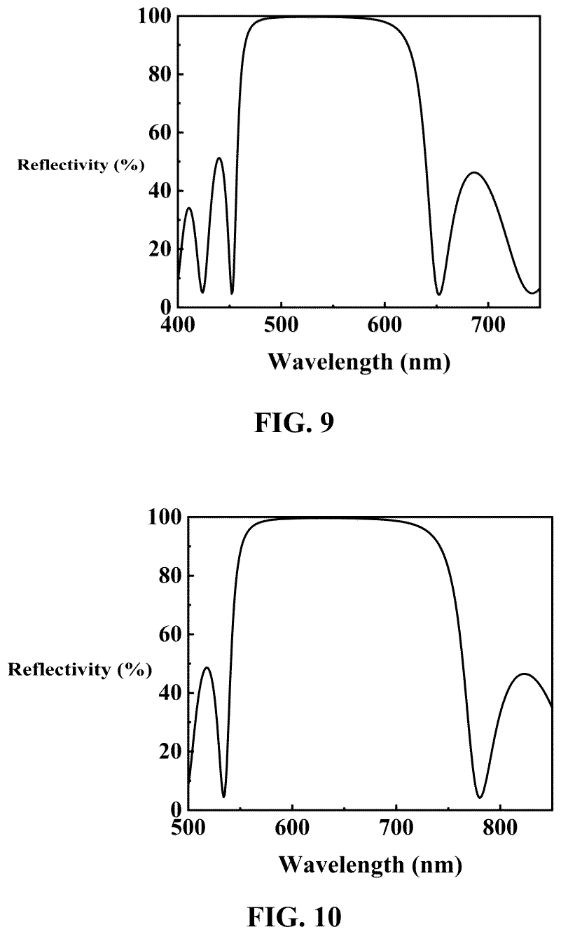

A Micro-LED chip provided by this embodiment is basically the same as that of Embodiment 3, the difference is that the Micro-LED chip structure is a green-light LED chip structure, which has a central wavelength of about 550 nm. The dielectric layer is a structure of eight pairs of TiO₂/SiO₂ composite layers, and a total thickness of the dielectric layer is 1112.0 nm, where the TiO₂ layer and the SiO₂ layer are alternately stacked to form a distributed Bragg reflector structure, each TiO₂ layer has a thickness of about 46.9 nm, and each SiO₂ layer has a thickness of about 92.1 nm. The reflectivity of the dielectric layer for light with different wavelengths is shown in FIG. 9. The dielectric layer can also cooperate with the metal optical isolation layer to eliminate the problem of optical crosstalk better and enhance the heat dissipation performance of the device, thereby improving photoelectric conversion efficiency and stability of the device.

### Embodiment 5

A Micro-LED chip provided by this embodiment is basically the same as that of Embodiment 3, the difference is that the Micro-LED chip structure is a green-light LED chip structure, which has a central wavelength of about 660 nm. The dielectric layer is a structure of eight pairs of TiO₂/SiO₂ composite layers, and a total thickness of the dielectric layer is 1350.4 nm, where the TiO₂ layer and the SiO₂ layer are alternately stacked to form a distributed Bragg reflector structure, each TiO₂ layer has a thickness of about 54.6 nm, and each SiO₂ layer has a thickness of about 114.2 nm. The reflectivity of the dielectric layer for light with different wavelengths is shown in FIG. 10. The dielectric layer can also cooperate with the metal optical isolation layer to eliminate the problem of optical crosstalk better and enhance the heat dissipation performance of the device, thereby improving photoelectric conversion efficiency and stability of the device.

The foregoing embodiments only illustrate the principle and efficacy of the present disclosure, and are not used to limit the present disclosure. Anyone skilled in the art can modify or change the foregoing embodiments without deviating from the spirit and scope of the present disclosure. Therefore, all equivalent modifications or changes made by those of ordinary skilled in the art without departing from the spirit and technical ideas disclosed in the present disclosure should still be covered by the claims of the present disclosure.

What is claimed is:

1. (canceled)

2. (canceled)

3. (canceled)

4. (canceled)

5. (canceled)

6. (canceled)

7. (canceled)

8. (canceled)

9. (canceled)

10. (canceled)

11. A micro-optoelectronic chip, comprising:
a substrate;
a semiconductor structure layer disposed on the substrate, wherein the semiconductor structure layer comprises a first doped semiconductor layer, an active layer and a second doped semiconductor layer which are laminated on the substrate in turn;
an ion-implanted region distributed in the semiconductor structure layer, wherein the ion-implanted region continuously extends at least from a top end surface of the second doped semiconductor layer to a top end surface of the active layer and is configured to electrically isolate a plurality of optoelectronic chip structures arranged in an array in the semiconductor structure layer;
an isolation trench formed in the ion-implanted region, wherein the isolation trench is at least configured to isolate second doped semiconductor layers of any two adjacent optoelectronic chip structures from each other, the whole isolation trench is located in a corresponding ion-implanted region, a spacing exists between an inner wall of the isolation trench and an outer wall of the corresponding ion-implanted region, a bottom surface of the isolation trench is higher than a bottom end surface of the corresponding ion-implanted region and is flush with a bottom end surface of the second doped semiconductor layer or lower than the bottom end surface of the second doped semiconductor layer, and the top end surface of the second doped semiconductor layer is one side surface, away from the substrate, of the second doped semiconductor layer;
a plurality of dielectric layers continuously covering at least a sidewall of the isolation trench, wherein the plurality of dielectric layers have different refractive indexes, and are stacked on the sidewall of the isolation trench in turn and are combined with the corresponding ion-implanted region to form a distributed Bragg reflector structure; and
a light-blocking structure arranged in the isolation trench, wherein the light-blocking structure is at least configured to prevent light from transmitting between any two adjacent optoelectronic chip structures through the second doped semiconductor layer and comprises a metal optical isolation layer that continuously covers at least the dielectric layer.

12. The micro-optoelectronic chip according to claim 11, wherein the bottom end surface of the ion-implanted region is located in the first doped semiconductor layer, a notch of the isolation trench is arranged on the top end surface of the second doped semiconductor layer, while a bottom of the isolation trench is located in the first doped semiconductor layer; and the light-blocking structure is at least configured to prevent light from transmitting between any two adjacent optoelectronic chip structures through the second doped semiconductor layer and the active layer.

13. The micro-optoelectronic chip according to claim 11, wherein a material of the dielectric layer comprises silicon oxide, silicon nitride, aluminum nitride, aluminum oxide, gallium oxide, or hafnium oxide.

14. The micro-optoelectronic chip according to claim 11, wherein the micro-optoelectronic chip further comprises a heat-conduction passivation layer, wherein the heat-conduction passivation layer covers a surface of the semiconductor structure layer and is in heat-conduction connection with the metal optical isolation layer.

15. The micro-optoelectronic chip according to claim 11, wherein the metal optical isolation layer further extends to cover a surface of the semiconductor structure layer to form a current spreading layer.

16. The micro-optoelectronic chip according to claim 11, wherein
a material of the metal optical isolation layer comprises gold, titanium, aluminum, nickel, chromium, molybdenum, or copper.

17. The micro-optoelectronic chip according to claim 11, wherein the ion-implanted region is arranged around a corresponding optoelectronic chip structure, and a size of each of the ion-implanted region and the optoelectronic chip structure ranges from 1 μm to 50 μm.

18. The micro-optoelectronic chip according to claim 11, wherein implanted ions for forming the ion-implanted region comprise H ions, F ions, N ions, or O ions.

19. The micro-optoelectronic chip according to claim 11, wherein a distance from the inner wall of the isolation trench to the outer wall of the corresponding ion-implanted region ranges from 100 nm to 20 μm.

20. The micro-optoelectronic chip according to claim 11, wherein a material of the semiconductor structure layer comprises III-V compounds

21. The micro-optoelectronic chip according to claim 20, wherein the material of the semiconductor structure layer comprises III nitrides.

22. The micro-optoelectronic chip according to claim 11, wherein the optoelectronic chip structure comprises a Micro-LED (Light Emitting Diode) chip structure.

23. A fabrication method for a micro-optoelectronic chip, comprising:
forming a semiconductor structure layer on a substrate, wherein the semiconductor structure layer comprises a first doped semiconductor layer, an active layer and a second doped semiconductor layer which are laminated on the substrate in turn;
carrying out ion implantation processing on the semiconductor structure layer at least from a top end surface of the second doped semiconductor layer with an ion implantation depth that at least reaches a top end surface of the active layer to form an ion-implanted region in the semiconductor structure layer, thereby electrically isolating a plurality of optoelectronic chip structures arranged in an array in the semiconductor structure layer, wherein the top end surface of the second doped semiconductor layer is one side surface, away from the substrate, of the second doped semiconductor layer;
etching the ion-implanted region with an etching depth that is less than the ion implantation depth but at least reaches a bottom end surface of the second doped semiconductor layer to form an isolation trench in the ion-implanted region, and enabling a presence of a spacing between an inner wall of the isolation trench and an outer wall of the ion-implanted region, thereby at least isolating second doped semiconductor layers of any two adjacent optoelectronic chip structures from each other;
forming a plurality of alternately stacked dielectric layers with different refractive indexes at least on a sidewall of the isolation trench, enabling the dielectric layers to continuously cover at least the sidewall of the isolation trench, and combining the plurality of dielectric layers with the ion-implanted region to form a distributed Bragg reflector structure;
fabricating a metal optical isolation layer, and enabling the metal optical isolation layer to continuously cover at least the dielectric layer to form a light-blocking structure in the isolation trench, thereby at least preventing light from transmitting between any two adjacent optoelectronic chip structures through the second doped semiconductor layer.

24. The fabrication method according to claim 23, comprising the following steps:
carrying out ion implantation processing on the semiconductor structure layer at least from the top end surface of the second doped semiconductor layer, wherein the ion implantation depth at least reaches an interior of the first doped semiconductor layer, thereby forming the ion-implanted region;
etching the ion-implanted region with an etching depth that is less than the ion implantation depth but at least reaches the interior of the first doped semiconductor layer, thereby forming the isolation trench; and
arranging the light-blocking structure in the isolation trench to at least prevent the light from transmitting between any two adjacent optoelectronic chip structures through the second doped semiconductor layer and the active layer.

25. The fabrication method according to claim 23, wherein a material of the dielectric layer comprises silicon oxide, silicon nitride, aluminum nitride, aluminum oxide, gallium oxide, or hafnium oxide.

26. The fabrication method according to claim 23, further comprising forming a heat-conduction passivation layer on a surface of the semiconductor structure layer, and enabling the heat-conduction passivation layer to be in heat-conduction connection with the metal optical isolation layer.

27. The fabrication method according to claim 26, wherein a material of the heat-conduction passivation layer comprises aluminum nitride, boron nitride, or diamond.

28. The fabrication method according to claim 23, further comprising enabling the metal optical isolation layer to extend to cover a surface of the semiconductor structure layer to form a current spreading layer.

29. The fabrication method according to claim 23, wherein a material of the metal optical isolation layer comprises gold, titanium, aluminum, nickel, chromium, molybdenum or copper.

30. The fabrication method according to claim 23, wherein the ion-implanted region is arranged around a corresponding optoelectronic chip structure, and a size of each of the ion-implanted region and the optoelectronic chip structure ranges from 1 μm to 50 μm.

31. The fabrication method according to claim 23, wherein implanted ions configured for ion implantation processing comprise H ions, F ions, N ions, or O ions.

32. The fabrication method according to claim 23, wherein a distance from the inner wall of the isolation trench to the outer wall of the corresponding ion-implanted region ranges from 100 nm to 20 μm.

33. The fabrication method according to claim 23, wherein a material of the semiconductor structure layer comprises III-V compounds.

34. The fabrication method according to claim 33, wherein the material of the semiconductor structure layer comprises III nitrides.

35. The fabrication method according to claim 23, wherein the optoelectronic chip structure comprises a Micro-LED chip structure.

36. A Micro-LED apparatus, comprising the micro-optoelectronic chip according to claim 11.
